(19) United States
(12) Patent Application Publication
(10) Pub. No.: US 2016/0293477 A1
(43) Pub. Date: Oct. 6, 2016

(54) SILICON-ON-INSULATOR (SOI) WAFERS EMPLOYING MOLDED SUBSTRATES TO IMPROVE INSULATION AND REDUCE CURRENT LEAKAGE

(71) Applicant: QUALCOMM Incorporated, San Diego, CA (US)

(72) Inventors: Daeik Daniel Kim, Del Mar, CA (US); Changhan Hobie Yun, San Diego, CA (US); Je-Hsiung Jeffrey Lan, San Diego, CA (US); Mario Francisco Velez, San Diego, CA (US); Jonghae Kim, San Diego, CA (US); Matthew Michael Nowak, San Diego, CA (US)

(21) Appl. No.: 14/856,418

(22) Filed: Sep. 16, 2015

Related U.S. Application Data
(60) Provisional application No. 62/140,121, filed on Mar. 30, 2015.

(51) Int. Cl. H01L 21/762; H01L 23/29; H01L 23/31; H01L 27/12; H01L 21/84

(52) U.S. Cl. CPC H01L 21/76256; H01L 27/1203; H01L 21/84; H01L 23/3157; H01L 23/291

(57) ABSTRACT

Silicon-on-insulator (SOI) wafers employing molded substrates to improve insulation and reduce current leakage are provided. In one aspect, a SOI wafer comprises a substrate. An insulating layer (e.g., a buried oxide (BOX) layer) is disposed above the substrate to insulate an active semiconductor layer disposed above the insulating layer, from the substrate. Transistors are formed in the active semiconductor layer. To provide for improved insulation between the active semiconductor layer and the substrate to reduce leakage and improve performance of the active semiconductor layer, the substrate is provided in the form of a molded substrate. A coating layer is also disposed between the molded substrate and the insulating layer of the SOI wafer, in case, for example, the melting temperature of a molding compound used to form the molded substrate is not low enough to prevent contamination of the active semiconductor layer into the insulating layer.

### PRIORITY CLAIM

The present application claims priority under 35 U.S.C. §119(e) to U.S. Provisional Patent Application Ser. No. 62/140,121 filed on Mar. 30, 2015 and entitled “SILICON-ON-INSULATOR (SOI) WAFERS EMPLOYING MOLDED SUBSTRATES TO IMPROVE INSULATION AND REDUCE LEAKAGE,” the contents of which is incorporated herein by reference in its entirety.

### BACKGROUND

I. Field of the Disclosure

The technology of the disclosure relates generally to forming transistors in silicon-on-insulator (SOI) wafers.

II. Background

In silicon-on-insulator (SOI) wafers, transistors are formed in thin layers of silicon that are isolated from the main body of the SOI wafer handle substrate by a layer of an electrical insulator, usually silicon dioxide. The silicon layer thickness ranges from several microns for electrical power switching devices to less than 500 Angstroms for high-performance microprocessors. Isolating an active transistor from the rest of a silicon substrate reduces electrical current leakage that would otherwise degrade the performance of the transistor. Since the area of electrically active silicon is limited to the immediate region around the transistor, switching speeds are increased and sensitivity to “soft errors” is greatly reduced.

In this regard, FIG. 1 is an exemplary SOI wafer 100. Instead of forming transistors in a bulk silicon layer, a transistor 102 is formed in a top, thin surface silicon layer 104 (“silicon layer 104”) above an underlying insulating layer 106 that is usually a few thousand Angstroms thick. The insulating layer 106 is formed on a handle substrate layer 108, which may be a silicon (Si) wafer and that provides the main body of the SOI wafer 100. The insulating layer 106 may be made out of silicon dioxide and referred to as a “buried oxide” or “BOX” layer to actively isolate the top silicon layer 104 from the silicon layer 108. The transistor 102 being formed within the isolated top silicon layer 104 allows for faster switching speeds, operation at lower voltages, and provides for the transistor 102 to be much less vulnerable to noise from background cosmic ray particles. Also, by each transistor 102 being isolated from its neighbor transistors (not shown) in the SOI wafer 100, the transistor 102 can be more closely located to other transistors 102 in the SOI wafer 100 to yield more chips per SOI wafer 100.

During the bonding process of the SOI wafer 100, a semiconductor layer may be formed between the insulating layer 106 and the bottom handle substrate layer 108 due to the high temperature, voltage, and pressure used to form the transistor 102. This causes the carriers of a depletion layer to move toward the insulating layer 106, and causes the semiconductor layer to be formed between the insulating layer 106 and the bottom handle substrate layer 108. This reduces the insulation between the transistor 102 and the handle substrate silicon layer 108, thereby increasing current leakage between the transistor 102 and adjacent transistors through the handle substrate layer 108. Depending on the application of the SOI wafer 100, this leakage may significantly impact performance of the circuits employing the transistor 102 in the SOI wafer 100.

### SUMMARY OF THE DISCLOSURE

Aspects disclosed in the detailed description include silicon-on-insulator (SOI) wafers employing molded substrates to improve insulation and reduce current leakage. Related methods and circuits are also disclosed. In this regard, in one aspect, a SOI wafer is provided. The SOI wafer comprises a substrate. An insulating layer, which may be a buried oxide (BOX) layer for example, is disposed above the substrate to insulate an active semiconductor layer disposed above the insulating layer, from the substrate. Transistors are formed in the active semiconductor layer that each have a channel region formed between a source and a drain. A buffer layer is disposed above the channel region to provide a dielectric layer between a gate and the channel region. To provide for improved insulation between active semiconductor layers and the substrate to reduce leakage and improve performance of the transistors formed in the active semiconductor layer, the substrate is provided in the form of a molded substrate comprised of a molding compound. In certain aspects, the molded substrate is molded on a back side of the SOI wafer, after the SOI wafer is formed with a bottom silicon layer substrate and the bottom silicon layer substrate is removed, such as through a grinding and/or etching process, which might be available in a back-end-of-line (BEOL) process, as non-limiting examples.

In one aspect, the molding compound has a lower melting temperature so that the molded substrate can be formed in the SOI wafer at lower temperatures conforming to back-end-of-line (BEOL) processes. This may reduce the risk of activating semiconductor material in an active semiconductor layer being diffused into the insulating layer, and thus into the molded substrate, thereby increasing current leakage. Nevertheless, a coating layer is also disposed on the back side of the insulating layer of the SOI wafer in aspects disclosed herein. The coating layer is disposed on the insulating layer before the molded substrate is molded on a back side of the SOI wafer. The coating layer is provided to further to prevent or reduce diffusion of the active semiconductor layer into the molded substrate during fabrication of the SOI wafer if the molding temperature for the molding compound could cause diffusion of the active semiconductor layer into the insulating layer during fabrication of the SOI wafer. The coating layer may also allow the molding compound to be used to form the molded substrate that does not require a lower melting temperature than may otherwise be needed or desired to further prevent or reduce diffusion of the active semiconductor layer into the molded substrate if the molded substrate was molded directly onto the back side of the insulating layer.

In this regard, in one exemplary aspect, a SOI wafer is provided. The SOI wafer comprises a molded substrate comprised of a molding compound. The SOI wafer also comprises an insulating layer disposed above the molded substrate. The SOI wafer also comprises an active semiconductor layer disposed above the insulating layer. The active semiconductor layer comprises a channel region disposed between a source and a drain. The SOI wafer also comprises a coating layer disposed on the insulating layer between the molded substrate and the insulating layer to prevent or reduce diffusion of the active semiconductor layer into the molded substrate.

In another exemplary aspect, a SOI wafer is provided. The SOI wafer comprises a means for providing a molding compound. The SOI wafer also comprises a means for insulating disposed above the means for providing the molding compound. The SOI wafer also comprises a means for providing active silicon devices disposed above the means for insulating. The means for providing the active silicon devices comprises a channel region disposed between a source and a drain. The SOI wafer also comprises a means for disposing a coating layer on the means for insulating between the means for providing the molding compound and the means for insulating to prevent or reduce diffusion of the active silicon devices into the means for providing the molding compound.

In another exemplary aspect, a method of fabricating a SOI wafer is provided. The method comprises forming a SOI wafer comprising a silicon layer substrate having a top side and a back side, the silicon layer substrate disposed on a bottom portion of the SOI wafer, an active semiconductor layer disposed above the silicon layer substrate, an insulating layer disposed between the silicon layer substrate and the active semiconductor layer and on the top side of the silicon layer substrate, and a passivation layer disposed above the active semiconductor layer on a top portion of the SOI wafer. The method also comprises attaching a carrier wafer to the passivation layer of the SOI wafer. The method also comprises removing at least a portion of the silicon layer substrate from the SOI wafer. The method also comprises disposing a coating layer on a back side of the insulating layer after removing the at least a portion of the silicon layer substrate from the SOI wafer. The method also comprises molding a molding compound on the back side of the insulating layer after the disposing of the coating layer on the back side of the insulating layer to form a molded substrate on the bottom portion of the SOI wafer.

### BRIEF DESCRIPTION OF THE FIGURES

FIG. 1 is a block diagram of an exemplary silicon-on-insulator (SOI) wafer employing a silicon layer substrate;

FIG. 2 a block diagram of an exemplary SOI wafer employing a molded substrate in place of a silicon layer substrate to improve insulation and reduce leakage;

FIGS. 3A-3G are block diagrams illustrating a SOI wafer being processed to include a coating layer and the molded substrate in the SOI wafer in FIG. 2;

FIGS. 4A-4C are flowcharts illustrating an exemplary process of forming the SOI wafer employing a coating layer and the molded substrate in the SOI wafer in FIG. 2; and

FIG. 5 is a block diagram of an exemplary processor-based system that can include circuits formed from SOI wafers employing molded substrates to improve insulation and reduce current leakage according to any of the aspects disclosed herein.

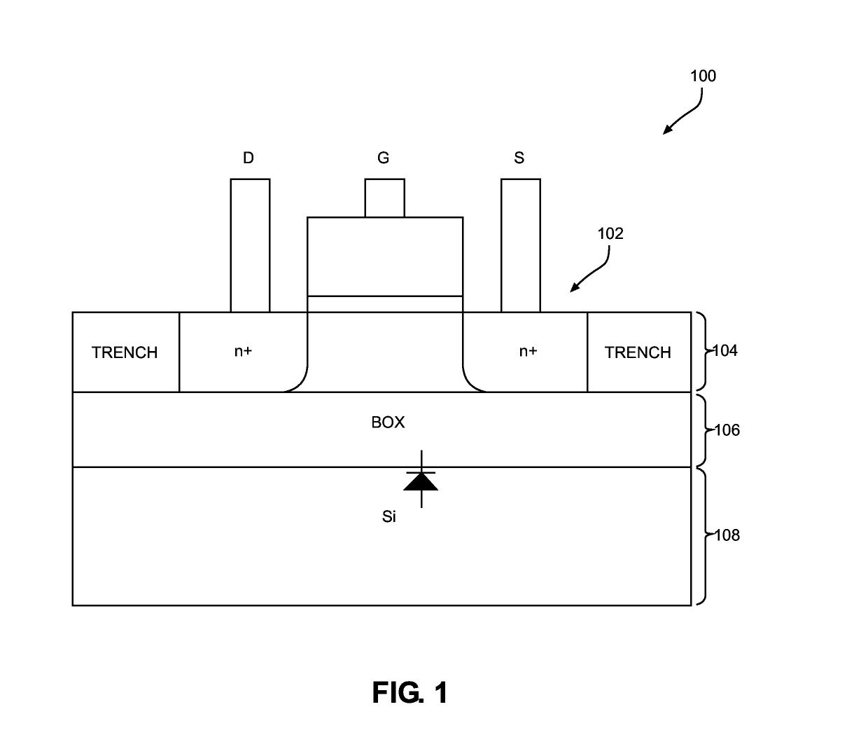

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include silicon-on-insulator (SOI) wafers employing molded substrates to improve insulation and reduce current leakage. Related methods and circuits are also disclosed. In this regard, in one aspect, a SOI wafer is provided. The SOI wafer comprises a substrate. An insulating layer, which may be a buried oxide (BOX) layer for example, is disposed above the substrate to insulate an active semiconductor layer disposed above the insulating layer, from the substrate. Transistors are formed in the active semiconductor layer that each have a channel region formed between a source and a drain. A buffer layer is disposed above the channel region to provide a dielectric layer between a gate and the channel region. To provide for improved insulation between active semiconductor layers and the substrate to reduce leakage and improve performance of the transistors formed in the active semiconductor layer, the substrate is provided in the form of a molded substrate comprised of a molding compound. In certain aspects, the molded substrate is molded on a back side of the SOI wafer, after the SOI wafer is formed with a bottom silicon layer substrate and the bottom silicon layer substrate is removed, such as through a grinding and/or etching process, which might be available as a back-end-of-line (BEOL) process, as non-limiting examples.

In one aspect, the molding compound has a lower melting temperature so that the molded substrate can be formed in the SOI wafer at lower temperatures conforming to back-end-of-line (BEOL) processes. This may reduce the risk of activating semiconductor material in an active semiconductor layer being diffused into the insulating layer, and thus into the molded substrate, thereby increasing current leakage. Nevertheless, a coating layer is also disposed on the back side of the insulating layer of the SOI wafer in aspects disclosed herein. The coating layer is disposed on the insulating layer before the molded substrate is molded on a back side of the SOI wafer. The coating layer is provided to further to prevent or reduce diffusion of the active semiconductor layer into the molded substrate during fabrication of the SOI wafer if the molding temperature for the molding compound could cause diffusion of the active semiconductor layer into the insulating layer during fabrication of the SOI wafer. The coating layer may also allow the molding compound to be used to form the molded substrate that does not require a lower melting temperature than may otherwise be needed or desired to further prevent or reduce diffusion of the active semiconductor layer into the molded substrate if the molded substrate was molded directly onto the back side of the insulating layer.

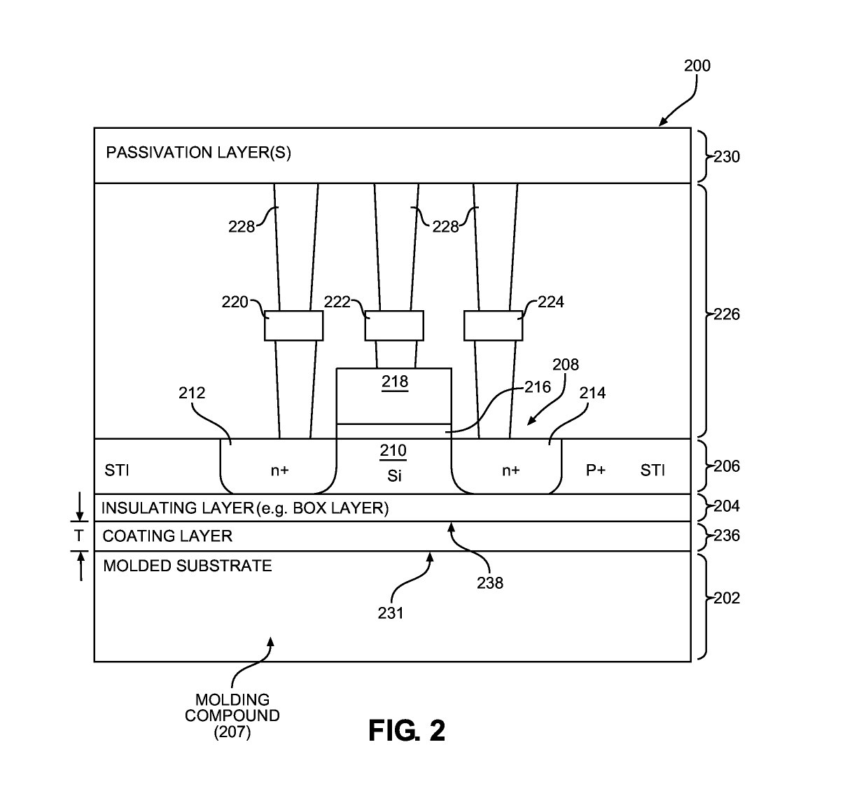

In this regard, FIG. 2 is a block diagram of an exemplary SOI wafer 200 employing a molded substrate 202 to improve insulation and reduce leakage. This is opposed to a silicon layer substrate in a typical SOI wafer. As shown in FIG. 2, an insulating layer 204 is provided in the SOI wafer 200. The insulating layer 204 may be a buried oxide (BOX) layer, and is thus also referred to herein as “BOX layer 204.” The BOX layer 204 is disposed above the molded substrate 202 to insulate an active semiconductor layer 206, disposed above the BOX layer 204, from the molded substrate 202. The molded substrate 202 may be formed from a molding compound 207, such as a polymer, an elastomer, a composite material, thermoplastic material, thermoset material, and silicone, etc., which is disposed on the BOX layer 204 of the SOI wafer 200. The BOX layer 204 may be one (1) micrometer (μm) thick, as a non-limiting example. A transistor 208 is formed in the active semiconductor layer 206 that has a channel region 210 formed between a source 212 and a drain 214. In this example, the transistor 208 is an n-type Metal Oxide Semiconductor Field-Effect Transistor (MOSFET) (nMOS) with an n-type material (n+) source 212 and drain 214, and P+material channel region 210. A buffer layer 216 is disposed above the channel region 210 to provide a dielectric layer between a gate 218 and the channel region 210. A source electrode 220, a gate electrode 222, and a drain electrode 224 are formed in a connectivity layer 226 disposed above the active semiconductor layer 206 from establishing connections to the source 212, the gate 218, and the drain 214, respectively. Inter-layer vias 228 or other connectivity structures are used to connect the source electrode 220, the gate electrode 222, and the drain electrode 224 to higher layers. A passivation layer(s) 230 may be disposed above the source electrode 220, the gate electrode 222, and the drain electrode 224 to reduce current leakage.

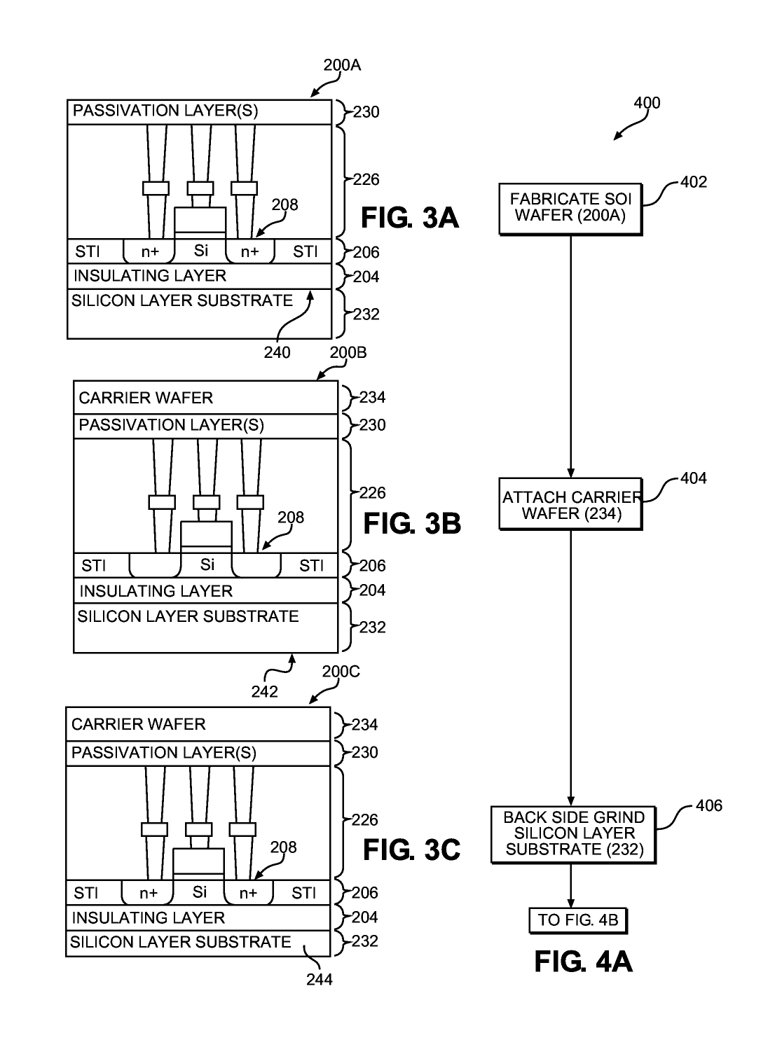

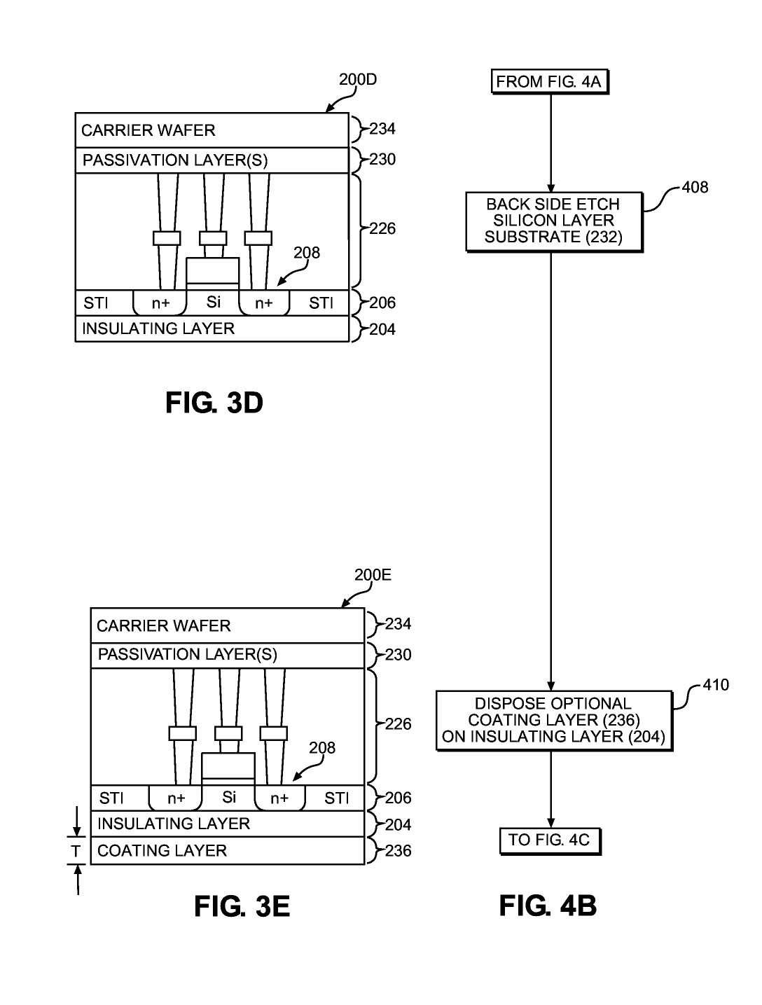

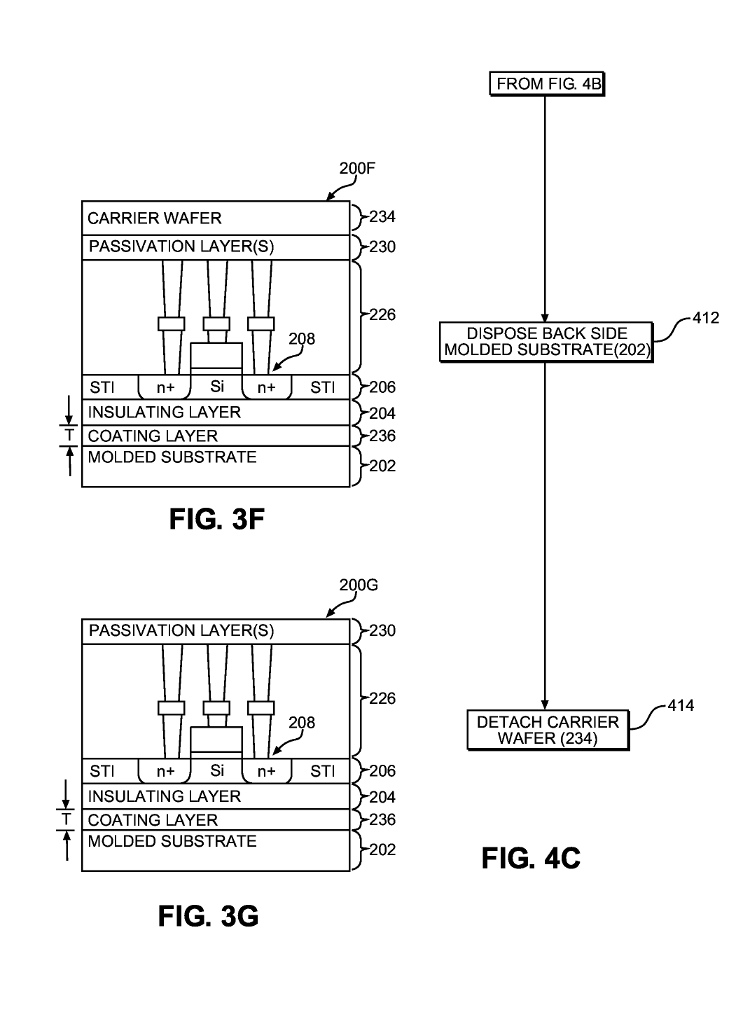

In certain aspects, as will be discussed in more detail below, the molded substrate 202 is molded on a back side 231 of the SOI wafer 200, after the SOI wafer 200 is formed with a bottom silicon layer substrate and the bottom silicon layer substrate (shown in FIGS. 3A and 3B and discussed below) is removed, as shown in FIG. 2. For example, the bottom silicon layer substrate may be fully or partially removed through a grinding and/or etching process, that might be available at a back-end-of-line (BEOL) process(es). Removing or substantially removing the bottom silicon layer substrate in the SOI wafer 200 can reduce or remove non-linearity of the transistor 208 in the active semiconductor layer 206 for increased performance, and at a lower cost than a conventional semiconductor device. As discussed above, providing the molded substrate 202 in the SOI wafer 200 in place of a bottom silicon layer substrate that is initially provided in the fabricated SOI wafer 200 can improve insulation and reduce leakage of the active semiconductor layer 206 through the SOI wafer 200. This may be particularly important if the SOI wafer 200 is employed in radio-frequency (RF) circuit applications in which isolation of the active semiconductor layer 206 may be important for performance of RF circuits employing the SOI wafer 200. Even though the molding compound 207 of the molded substrate 202 in the SOI wafer 200 in FIG. 2 may have impurities, the process of disposing the molded substrate 202 on the SOI wafer 200 can be performed at relatively lower temperatures, such as 200 degrees Celsius or lower. Thus, front end-of-line (FEOL) structures, including the active semiconductor layer 206, are not damaged during fabrication. However, there still may be a risk of activation of semiconductor material in the active semiconductor layer 206 being diffused into the BOX layer 204 and the molded substrate 202 during the fabrication process. If this is a concern, a coating layer 236 can be provided in the SOI wafer 200, as shown in FIG. 2. The coating layer 236 can be provided as an additional oxide layer or nitride layer as non-limiting examples. The coating layer 236 is disposed below the BOX layer 204 between the molded substrate 202 and the BOX layer 204, and on a back side 238 of the BOX layer 204 in this example. The coating layer 236 can prevent or reduce contamination of the BOX layer 204 with the molded substrate 202 so that any diffusion of the active semiconductor layer 206 into the BOX layer 204 is insulated from the molded substrate 202 by the coating layer 236.

FIGS. 3A-3G are block diagrams illustrating exemplary SOI wafers 200A-200G being processed to include the molded substrate 202 to form the SOI wafer 200 in FIG. 2. FIGS. 4A-4C are flowcharts illustrating an exemplary process 400 of forming the SOI wafer 200 employing the molded substrate 202 in FIG. 2.

In this regard, with reference to FIG. 3A, a SOI wafer 200A is first fabricated and formed with a silicon layer substrate 232 (block 402 in FIG. 4A). The BOX layer 204 is formed on a top side 240 of the silicon layer substrate 232 in this example. As discussed above, during the bonding process of the SOI wafer 200A, the active semiconducting layer 206 may be formed between the BOX layer 204 and the bottom silicon layer substrate 232 due to the high temperature, voltage, and pressure used to form the transistor 208. This causes the carriers of a depletion layer to move toward the BOX layer 204, and causes a semiconducting layer to be formed between the BOX layer 204 and the bottom silicon layer substrate 232. This reduces the insulation between the transistor 208 and the bottom silicon layer substrate 232, thereby increasing current leakage between the transistor 208 and adjacent transistors through the silicon layer substrate 232. To address this issue, as discussed below, the bottom silicon layer substrate 232 is replaced with the molded substrate 202.

In this regard, to replace the bottom silicon layer substrate 232 with the molded substrate 202, a first step may be to attach a temporary carrier wafer 234 to the SOI wafer 200A in FIG. 3A to provide the SOI wafer 200B in FIG. 3B (block 404 in FIG. 4A). Attaching the carrier wafer 234 to the SOI wafer 200B allows back side processing of the SOI wafer 200B after thinning without the risk of wafer breakage. The carrier wafer 234 gives mechanical stability and protects the fragile SOI wafer 200B. Next, to begin to remove the silicon layer substrate 232, at least a portion of a back side 242 of the silicon layer substrate 232 of the SOI wafer 200B is grinded down, as shown in the SOI wafer 200C in FIG. 3C (block 406 in FIG. 4A). As shown in FIG. 3C, a remaining portion 244 of the silicon layer substrate 232 remains, because in this example, the grinding process is not used to remove the entire silicon layer substrate 232. The grinding process is employed to grind down the SOI wafer 200C to a certain width, such as fifty (50) micrometers (μm) for example. This is so that a more refined process can be used to remove the remaining silicon layer substrate 232, as opposed to grinding the entire silicon layer substrate 232, which could damage the BOX layer 204 in this non-limiting example.

Next, as shown in FIG. 3D, a back side etching process may be employed to remove the remaining silicon layer substrate 232 in the SOI wafer 200C in FIG. 3C (block 408 in FIG. 4B). In this manner, an etch stop can be employed at the interface of the BOX layer 204 with the silicon layer substrate 232 to avoid damaging the BOX layer 204. For example, a chemical process may be employed to etch the remaining silicon layer substrate 232 in the SOI wafer 200C in FIG. 3C until the silicon layer substrate 232 is removed, as shown in the SOI wafer 200D in FIG. 3D.

As discussed above, even though the molding compound 207 of the molded substrate 202 may have impurities, the process of disposing the molded substrate 202 on the back side of the SOI wafer 200 can be performed at relatively lower temperatures, such as 200 degrees Celsius or lower. Thus, there may be a low risk of activation of semiconductor material in the active semiconductor layer 206 being diffused into the BOX layer 204 and the molded substrate 202. However, if this is a concern, the coating layer 236 can be provided. The coating layer 236 can be an additional oxide layer or nitride layer as examples to protect the transistor 208. In this regard, as shown in FIG. 3E, the coating layer 236 may next be applied to the back side of the SOI wafer 200D in FIG. 3D to the BOX layer 204 to form the SOI wafer 200E (block 410 in FIG. 4B). As discussed above, the coating layer 236 may be provided to prevent contamination of the BOX layer 204 with the molded substrate 202 that will next be disposed on the back side as shown in the SOI wafer 200F in FIG. 3F. Examples of materials that can be used for the coating layer 236 include, but are not limited to a polymer, an elastomer, a composite, thermoplastic material, thermoset material, silicone, etc. The coating layer 236 may be, for example, 500-2000 Angstroms (A) in thickness (T) to block the impurities from contaminating the BOX layer 204 in subsequent processing steps of the SOI wafer 200E.

As shown in FIG. 3F, the molded substrate 202 is next disposed on the back side of the coating layer 236 to form the SOI wafer 200F (block 412 in FIG. 4C). The molded substrate 202 is comprised of a molding compound 207 in one example that can melt at lower temperatures, such as less than 200 degrees Celsius. The molding compound 207 may be comprised of a polymer as one non-limiting example. The process of molding the molded substrate 202 to the SOI wafer 200 can be a wafer level molding. The molding compound 207 can be applied to the back side of the SOI wafer 200 to provide the molded substrate 202. Also, the molding compound 207 can be applied at lower temperatures, such as less than 200 degrees Celsius, which will not risk activation of semiconductor material in the active semiconductor layer 206 being diffused into the BOX layer 204 and the molded substrate 202, and thus be compatible with BEOL processes for the SOI wafer 200. Examples of molding compounds 207 will have improved radio frequency (RF) properties at lower temperatures with a low dielectric constant (e.g., <=4).

Lastly, in this example, the carrier wafer 234 can then be removed from the SOI wafer 200F in FIG. 3F to provide the SOI wafer 200G in FIG. 3G (block 414 in FIG. 4C).

SOI wafers employing molded substrates to improve insulation and reduce current leakage according to aspects disclosed herein, may be provided in or integrated into in any processor-based device. Examples, without limitation, include a set top box, an entertainment unit, a navigation device, a communications device, a fixed location data unit, a mobile location data unit, a mobile phone, a cellular phone, a smart phone, a tablet, a phablet, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, and an automobile.

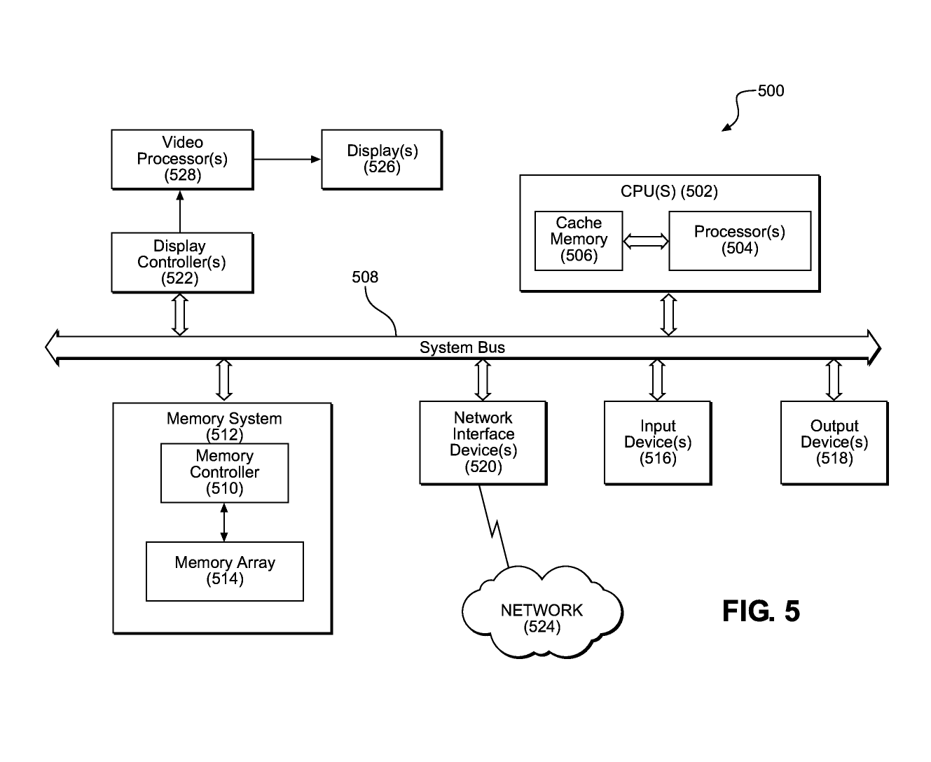

In this regard, FIG. 5 illustrates an example of a processor-based system 500 that can employ SOI wafers employing molded substrates to improve insulation and reduce leakage according to any of the particular aspects discussed above. In this example, the processor-based system 500 includes one or more central processing units (CPUs) 502, each including one or more processors 504. The CPU(s) 502 may have cache memory 506 coupled to the processor(s) 504 for rapid access to temporarily stored data. The CPU(s) 502 is coupled to a system bus 508 and can intercouple master and slave devices included in the processor-based system 500. As is well known, the CPU(s) 502 communicates with these other devices by exchanging address, control, and data information over the system bus 508. For example, the CPU(s) 502 can communicate bus transaction requests to a memory controller 510 in a memory system 512 as an example of a slave device. Although not illustrated in FIG. 5, multiple system buses 508 could be provided, wherein each system bus 508 constitutes a different fabric. In this example, the memory controller 510 is configured to provide memory access requests to a memory array 514 in the memory system 512.

Other devices can be connected to the system bus 508. As illustrated in FIG. 5, these devices can include the memory system 512, one or more input devices 516, one or more output devices 518, one or more network interface devices 520, and one or more display controllers 522, as examples. The input device(s) 516 can include any type of input device, including but not limited to input keys, switches, voice processors, etc. The output device(s) 518 can include any type of output device, including but not limited to audio, video, other visual indicators, etc. The network interface device(s) 520 can be any devices configured to allow exchange of data to and from a network 524. The network 524 can be any type of network, including but not limited to a wired or wireless network, a private or public network, a local area network (LAN), a wireless local area network (WLAN), a wide area network (WAN), a BLUETOOTH™ network, and the Internet. The network interface device(s) 520 can be configured to support any type of communications protocol desired.

The CPU(s) 502 may also be configured to access the display controller(s) 522 over the system bus 508 to control information sent to one or more displays 526. The display controller(s) 522 sends information to the display(s) 526 to be displayed via one or more video processors 528, which process the information to be displayed into a format suitable for the display(s) 526. The display(s) 526 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A silicon-on-insulator (SOI) wafer, comprising:
a molded substrate comprised of a molding compound;
an insulating layer disposed above the molded substrate;
an active semiconductor layer disposed above the insulating layer, the active semiconductor layer comprising a channel region disposed between a source and a drain; and
a coating layer disposed on the insulating layer between the molded substrate and the insulating layer to prevent or reduce diffusion of the active semiconductor layer into the molded substrate.

2. The SOI wafer of claim 1, wherein the coating layer is disposed on a back side of the insulating layer.

3. The SOI wafer of claim 1, wherein the coating layer is comprised of an oxide layer.

4. The SOI wafer of claim 1, wherein the coating layer is comprised of a nitride layer.

5. The SOI wafer of claim 1, wherein the coating layer has a thickness between 500-2000 Angstroms (A)

6. The SOI wafer of claim 1, wherein the molding compound is comprised of a material selected from the group consisting of a polymer, an elastomer, a composite material, a thermoplastic material, a thermoset material, and silicone.

7. The SOI wafer of claim 1, wherein the molding compound can melt at temperatures below 200 degrees Celsius.

8. The SOI wafer of claim 1, wherein the molding compound has a dielectric constant less than or equal to four (4).

9. The SOI wafer of claim 1, wherein the insulating layer is comprised of a buried oxide (BOX) layer.

10. The SOI wafer of claim 1 integrated into an integrated circuit (IC).

11. The SOI wafer of claim 1 integrated into a device selected from the group consisting of: a set top box; an entertainment unit; a navigation device; a communications device; a fixed location data unit; a mobile location data unit; a mobile phone; a cellular phone; a smart phone; a tablet; a phablet; a computer; a portable computer; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; and an automobile.

12. A silicon-on-insulator (SOI) wafer, comprising:
a means for providing a molding compound;
a means for insulating disposed above the means for providing the molding compound;
a means for providing active silicon devices disposed above the means for insulating, the means for providing the active silicon devices comprising a channel region disposed between a source and a drain; and
a means for disposing a coating layer on the means for insulating between the means for providing the molding compound and the means for insulating to prevent or reduce diffusion of the active silicon devices into the means for providing the molding compound.

13. The SOI wafer of claim 12, wherein the means for disposing the coating layer is disposed on a back side of the means for insulating.

14. A method of fabricating a silicon-on-insulator (SOI) wafer, comprising:
forming a SOI wafer, comprising a silicon layer substrate having a top side and a back side, the silicon layer substrate disposed on a bottom portion of the SOI wafer, an active semiconductor layer disposed above the silicon layer substrate, an insulating layer disposed between the silicon layer substrate and the active semiconductor layer and on the top side of the silicon layer substrate, and a passivation layer disposed above the active semiconductor layer on a top portion of the SOI wafer;
attaching a carrier wafer to the passivation layer of the SOI wafer;
removing at least a portion of the silicon layer substrate from the SOI wafer;
disposing a coating layer on a back side of the insulating layer after removing the at least a portion of the silicon layer substrate from the SOI wafer; and
molding a molding compound on the back side of the insulating layer after the disposing of the coating layer on the back side of the insulating layer to form a molded substrate on the bottom portion of the SOI wafer.

15. The method of claim 14, wherein removing the at least a portion of the silicon layer substrate from the SOI wafer comprises removing the silicon layer substrate from the SOI wafer.

16. The method of claim 14, wherein removing the at least a portion of the silicon layer substrate from the SOI wafer comprises removing the back side of the silicon layer substrate to remove the at least a portion of the silicon layer substrate from the SOI wafer leaving a remaining portion of the silicon layer substrate to avoid damaging the insulating layer.

17. The method of claim 16, wherein removing the at least a portion of the silicon layer substrate from the SOI wafer comprises grinding the back side of the silicon layer substrate to remove the at least a portion of the silicon layer substrate from the SOI wafer leaving the remaining portion of the silicon layer substrate to avoid damaging the insulating layer.

18. The method of claim 16, comprising removing the back side of the silicon layer substrate to remove the at least a portion of the silicon layer substrate from the SOI wafer leaving the remaining portion of the silicon layer substrate of a width less than or equal to fifty (50) micrometers (μm).

19. The method of claim 16, further comprising etching the remaining portion of the silicon layer substrate down to the insulating layer to remove the remaining portion of the silicon layer substrate from the SOI wafer.

20. The method of claim 14, further comprising detaching the carrier wafer from the SOI wafer after molding the molding compound on the back side of the insulating layer to form the molded substrate on the bottom portion of the SOI wafer.
